(19) United States
(12) Patent Application Publication
(10) Pub. No.: US 2023/0139299 A1
(43) Pub. Date: May 4, 2023

(54) MICRO-MIRROR DIE ATTACHED TO A PACKAGE SUBSTRATE THROUGH DIE ATTACH MATERIALS WITH DIFFERENT YOUNG'S MODULUSES

(71) Applicant: BEIJING VOYAGER TECHNOLOGY CO., LTD., Beijing (CN)

(72) Inventors: Sae Won LEE, Mountain View, CA (US); Youmin WANG, Mountain View, CA (US); Gary LI, Mountain View, CA (US)

(73) Assignee: BEIJING VOYAGER TECHNOLOGY CO., LTD., Beijing (CN)

(21) Appl. No.: 17/517,308

(22) Filed: Nov. 2, 2021

(51) Int. Cl. G02B 27/00; G02B 26/08; G02B 26/10; B81C 1/00; B81B 7/00

(52) U.S. Cl. CPC G02B 27/0081; B81B 7/0048; B81C 1/00317; G02B 26/101; G02B 26/0833; G02B 1/02

(57) ABSTRACT

Embodiments of the disclosure provide a packaged micro-mirror for an optical sensing system. In some embodiments, the packaged micro-mirror may include a package substrate. In some embodiments, the packaged micro-mirror may include a micro-mirror die attached to the package substrate through a first die attach material and a second die attach material. In some embodiments, the first die attach material may have a first Young’s modulus and the second die attach material may have a second Young’s modulus higher than the first Young’s modulus. In some embodiments, at least one of the first die attach material or the second die attach material may be a conductive adhesive forming an electrical connection between the micro-mirror die and package substrate.

### TECHNICAL FIELD

The present disclosure relates to a packaged micro-mirror for an optical sensing system in which a micro-mirror die is attached to the package substrate through a non-conductive die attach material with a first Young’s modulus and a conductive die attach material with a second Young’s modulus that is larger than the first Young’s modulus.

### BACKGROUND

Optical sensing systems, e.g., LiDAR systems, have been widely used in advanced navigation technologies, such as to aid autonomous driving or to generate high-definition maps. For example, a typical LiDAR system measures the distance to a target by illuminating the target with pulsed laser light beams and measuring the reflected pulses with a sensor. Differences in laser light return times, wavelengths, and/or phases can then be used to construct digital three-dimensional (3D) representations of the target. Because using a narrow laser beam as the incident light can map physical features with very high resolution, a LiDAR system is particularly suitable for applications such as sensing in autonomous driving and high-definition map surveys.

In a scanning LiDAR system, a wide field-of-view (FOV) is desired. With the demand for smaller and less-costly LiDAR systems, micro-electro-mechanical systems (MEMS) solutions have been proposed for steering, transmitting, and receiving light over a FOV. To achieve a desirable FOV for long-range and even mid-range object sensing, micro-mirror arrays may be used instead of a single large mirror. To simulate the operation of a single large mirror, the movement of individual micro-mirrors in the array is synchronized to direct light in a single direction. A micro-mirror array may be formed as a device chip (also referred to as a “die”) that includes different layers of material, such as silicon, silicon dioxide, silicon nitride, etc. For packaging into a scanner, the micro-mirror die is typically mounted on a package substrate using a conductive die attach material. The flatness of the micro-mirror array on the package substrate directly affects the scanner’s FOV. This is because deformation of the micro-mirror array increases the optical divergence of the outgoing light beam, which limits the scanner’s FOV.

Various factors may affect the flatness of micro-mirror die on the package substrate. These factors may include, e.g., the Young’s modulus and coefficient-of-thermal expansion (CTE) of the die attach material, as well as the CTE of the micro-mirror die and the package substrate. A micro-mirror die generally has a lower CTE than a ceramic package substrate. Thus, as the temperature within the package changes, the micro-mirror die and the package substrate may expand and/or contract at different rates. Different rates of expansion/contraction of these two materials may cause deformation of the micro-mirror die. This deformation may increase the optical divergence of the outgoing light beam, and hence, limit the scanner’s FOV. This problem may be exacerbated by the die attach material between the micro-mirror die and the package substrate. For example, while conductive die attach materials are desirable to establish an electrical connection with the micro-mirror die, the stiffness (e.g., high Young’s modulus) of conductive die attach materials may prevent them from relieving mechanical stress associated with micro-mirror die deformation. The micro-mirror die deformation then causes optical divergence, which decreases the FOV of scanner and limits the performance and accuracy of such a scanner.

Hence, there is an unmet need for a packaged micro-mirror that limits the amount of optical divergence due to CTE mismatch among the micro-mirror die, the package substrate, and the die attach material in between.

### SUMMARY

Embodiments of the disclosure provide a packaged micro-mirror for an optical sensing system. In some embodiments, the packaged micro-mirror may include a package substrate. In some embodiments, the packaged micro-mirror may include a micro-mirror die attached to the package substrate through a first die attach material and a second die attach material. In some embodiments, the first die attach material may have a first Young’s modulus and the second die attach material may have a second Young’s modulus higher than the first Young’s modulus. In some embodiments, at least one of the first die attach material or the second die attach material may be a conductive material forming an electrical connection between the micro-mirror die and package substrate.

Embodiments of the disclosure provide a scanner for an optical sensing system. In some embodiments, the scanner may include a packaged micro-mirror. In some embodiments, the packaged micro-mirror may include a package substrate. In some embodiments, the packaged micro-mirror may include a micro-mirror die attached to the package substrate through a first die attach material and a second die attach material. In some embodiments, the first die attach material may have a first Young’s modulus and the second die attach material may have a second Young’s modulus higher than the first Young’s modulus. In some embodiments, at least one of the first die attach material or the second die attach material may be a conductive material forming an electrical connection between the micro-mirror die and package substrate.

Embodiments of the disclosure provide an assembly method of a packaged micro-mirror. In some embodiments, the method may include applying a first die attach material to a first region of a package substrate. In some embodiments, the method may include applying a second die attach material to a second region of the package substrate. In some embodiments, the method may include positioning a micro-mirror die in contact with the first die attach material and the second die attach material. In some embodiments, the method may include bonding the micro-mirror die to the package substrate by the first die attach material and the second die attach material. In some embodiments, the first die attach material may have a first Young’s modulus and the second die attach material may have a second Young’s modulus higher than the first Young’s modulus.

It is to be understood that both the foregoing general description and the following detailed description are exemplary and explanatory only and are not restrictive of the invention, as claimed.

### BRIEF DESCRIPTION OF THE DRAWINGS

FIG. 1 illustrates a block diagram of an exemplary LiDAR system, according to embodiments of the disclosure.

FIG. 2A illustrates a first diagram of an exemplary package substrate assembly with different die attach materials formed thereon, according to embodiments of the disclosure.

FIG. 2B illustrates a first diagram of an exemplary packaged micro-mirror including a micro-mirror die and the package substrate assembly of FIG. 2A, according to embodiments of the disclosure.

FIG. 2C illustrates a second diagram of an exemplary package substrate assembly with different die attach materials formed thereon, according to embodiments of the disclosure.

FIG. 2D illustrates a second diagram of an exemplary packaged micro-mirror including a micro-mirror die and the package substrate assembly of FIG. 2C, according to embodiments of the disclosure.

FIG. 2E illustrates a third diagram of an exemplary package substrate assembly with different die attach materials formed thereon, according to embodiments of the disclosure.

FIG. 2F illustrates a third diagram of an exemplary packaged micro-mirror including a micro-mirror die and the package substrate assembly of FIG. 2E, according to embodiments of the disclosure.

FIG. 3 illustrates an exemplary process flow for assembling a packaged micro-mirror, according to embodiments of the disclosure.

FIG. 4 illustrates a flowchart of an exemplary method of assembling a packaged micro-mirror, according to embodiments of the disclosure.

### DETAILED DESCRIPTION

Reference will now be made in detail to the exemplary embodiments, examples of which are illustrated in the accompanying drawings. Wherever possible, the same reference numbers will be used throughout the drawings to refer to the same or like parts.

LiDAR is an optical sensing technology that enables autonomous vehicles to “see” the surrounding world, creating a virtual model of the environment to facilitate decision-making and navigation. An optical sensor (e.g., LiDAR transmitter and receiver) creates a 3D map of the surrounding environment using laser beams and time-of-flight (ToF) distance measurements. ToF, which is one of LiDAR’s operational principles, provides distance information by measuring the travel time of a collimated laser beam to reflect off an object and return to the sensor. Reflected light signals are measured and processed at the vehicle to detect, identify, and decide how to interact with or avoid objects.

Due to the challenges imposed by CTE mismatch, as discussed in the BACKGROUND section above, the present disclosure provides a packaged micro-mirror in which a die attach material with a low Young’s modulus is used to attach the micro-mirror die to the package substrate, in addition to a conductive die attach material with a higher Young’s modulus. The conductive die attach material enables electrical connection from the micro-mirror die to a control unit exterior to the package, while the low Young’s modulus die attach material may relieve mechanical stress buildup caused by CTE mismatch. By including a die attach material that can provide physical connection to the attachment while relieving the mechanical stress, the amount of micro-mirror die deformation associated with CTE mismatch may be minimized, thereby increasing the scanner’s FOV.

Some exemplary embodiments are described below with reference to a scanner used in LiDAR system(s), but the application of the scanning mirror assembly disclosed by the present disclosure is not limited to the LiDAR system. Rather, one of ordinary skill would understand that the following description, embodiments, and techniques may apply to any type of optical sensing system (e.g., biomedical imaging, 3D scanning, tracking and targeting, free-space optical communications (FSOC), and telecommunications, just to name a few) known in the art without departing from the scope of the present disclosure.

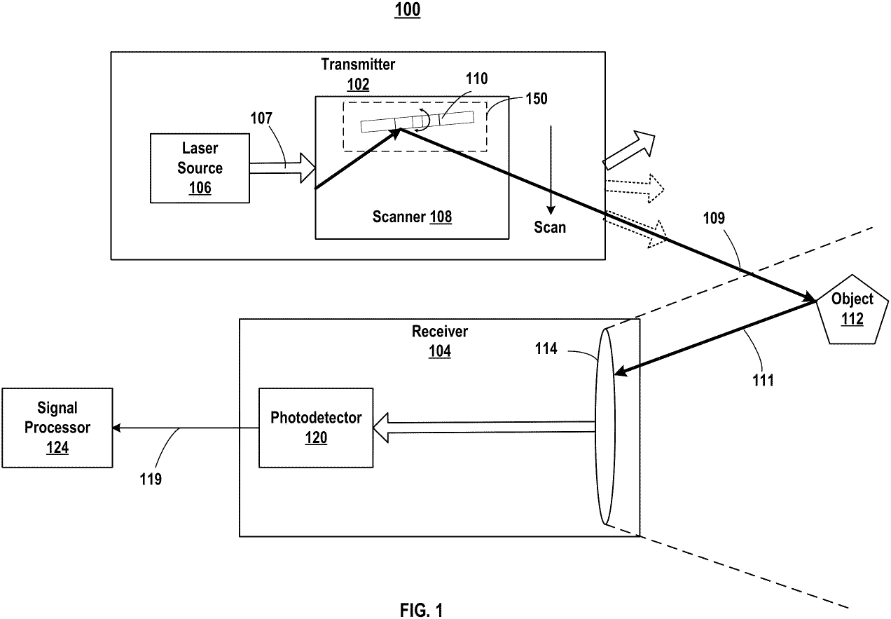

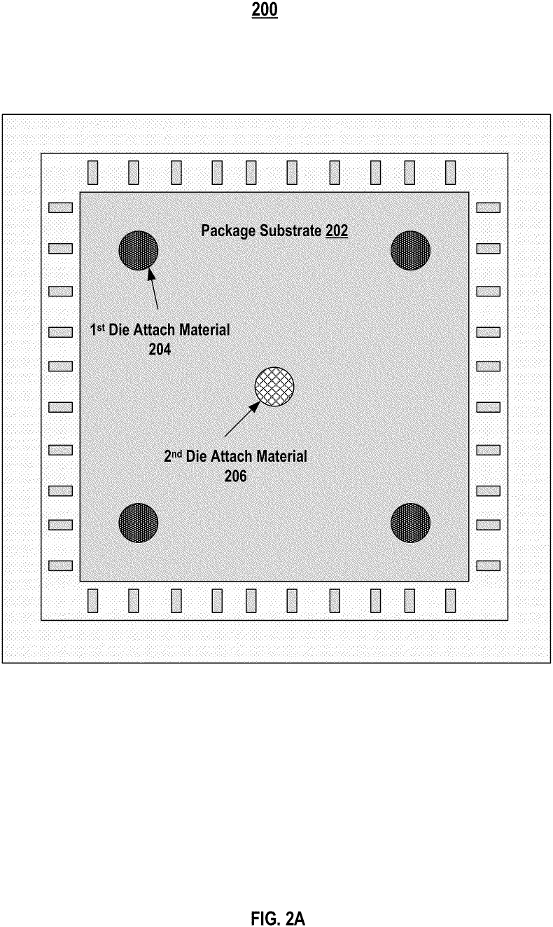

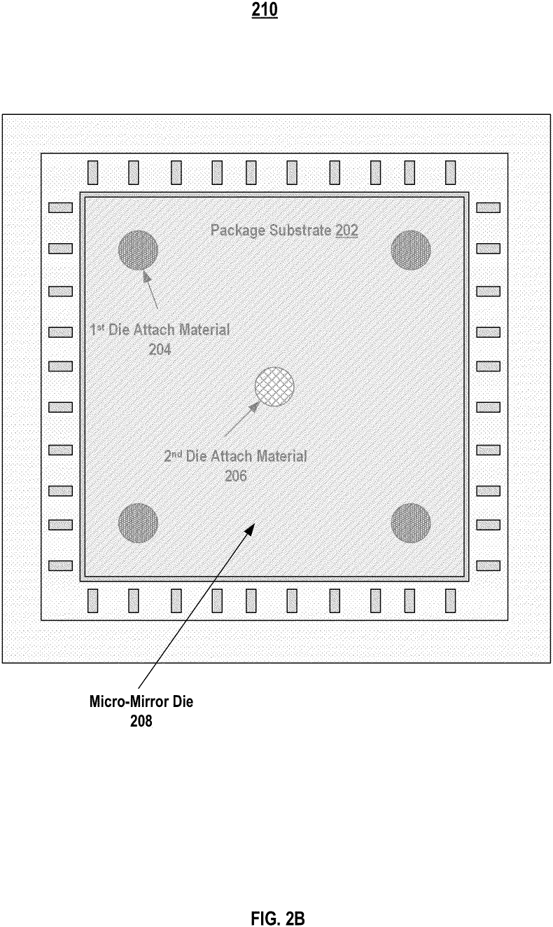

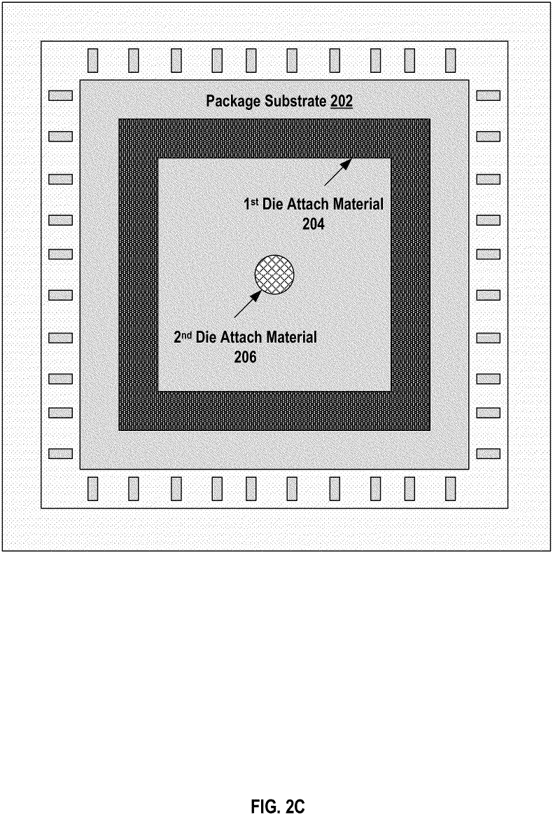

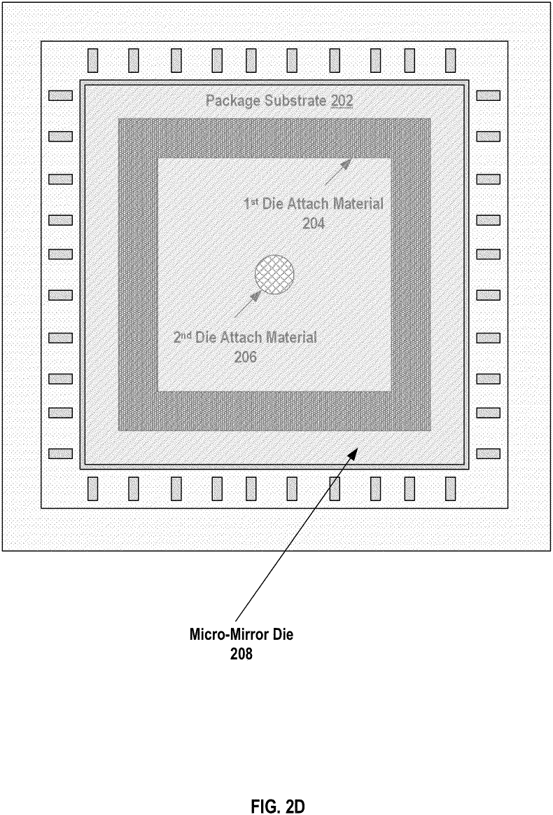

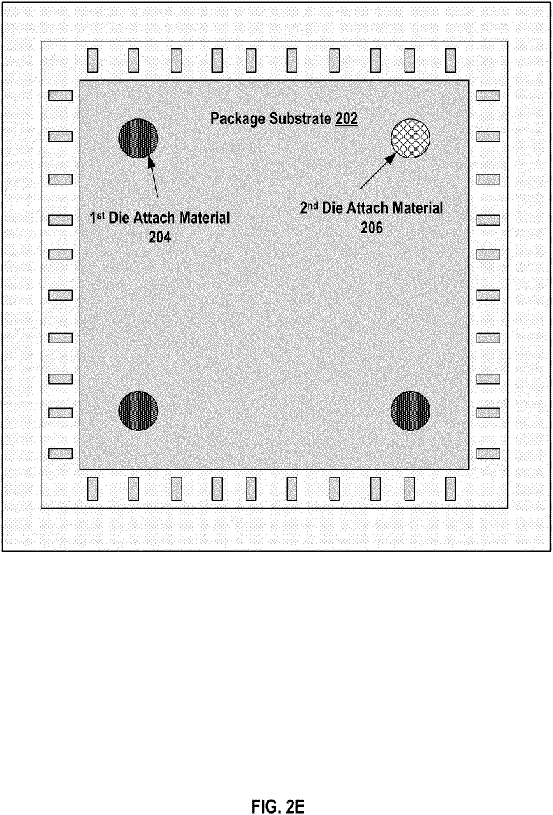

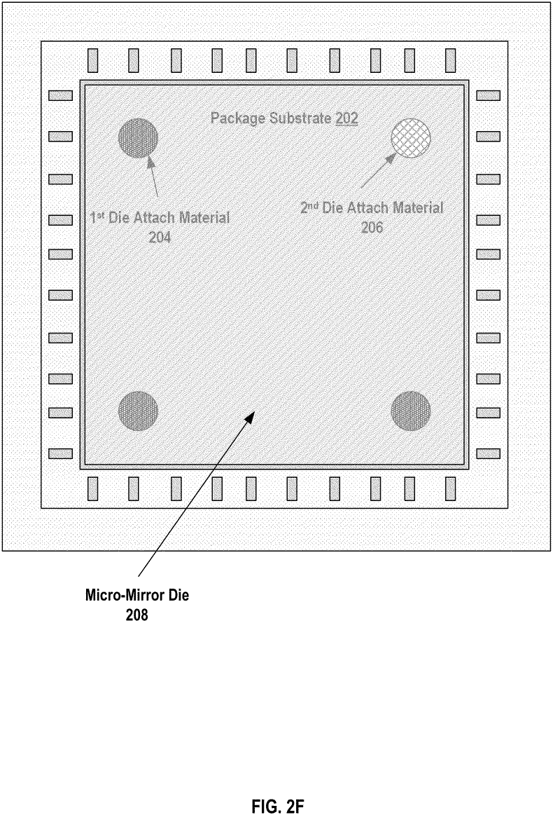

FIG. 1 illustrates a block diagram of an exemplary LiDAR system 100, according to embodiments of the disclosure. LiDAR system 100 may include a transmitter 102 and a receiver 104. Transmitter 102 may emit laser beams along multiple directions. Transmitter 102 may include one or more light source(s) 106 and a scanner 108. Scanner 108 of the exemplary LiDAR system 100 may include an exemplary packaged micro-mirror 150. Non-limiting examples of exemplary packaged micro-mirror 150 are depicted in FIGS. 2B, 2D, and 2F.

Transmitter 102 can sequentially emit a stream of pulsed laser beams in different directions within a scan range (e.g., a range in angular degrees), as illustrated in FIG. 1. Light source 106 may be configured to provide a laser beam 107 (also referred to as “native laser beam”) to scanner 108. In some embodiments of the present disclosure, light source 106 may generate a pulsed laser beam in the ultraviolet, visible, or near infrared wavelength range.

In some embodiments of the present disclosure, light source 106 may include a pulsed laser diode (PLD), a vertical-cavity surface-emitting laser (VCSEL), a fiber laser, etc. For example, a PLD may be a semiconductor device similar to a light-emitting diode (LED) in which the laser beam is created at the diode’s junction. In some embodiments of the present disclosure, a PLD includes a PIN diode in which the active region is in the intrinsic (I) region, and the carriers (electrons and holes) are pumped into the active region from the N and P regions, respectively. Depending on the semiconductor materials, the wavelength of incident laser beam 107 provided by a PLD may be greater than 700 nm, such as 760 nm, 785 nm, 808 nm, 848 nm, 905 nm, 940 nm, 980 nm, 1064 nm, 1083 nm, 1310 nm, 1370 nm, 1480 nm, 1512 nm, 1550 nm, 1625 nm, 1654 nm, 1877 nm, 1940 nm, 2000 nm, etc. It is understood that any suitable laser source may be used as light source 106 for emitting laser beam 107. In certain configurations, a collimating lens may be positioned between light source 106 and scanner 108 and configured to collimate laser beam 107 prior to impinging on the MEMS mirror 110. MEMS mirror 110, at its rotated angle, may deflect the laser beam 107 generated by light sources 106 to the desired direction, which becomes collimated laser beam 109.

Scanner 108 may be configured to steer a collimated laser beam 109 towards an object 112 (e.g., stationary objects, moving objects, people, animals, trees, fallen branches, debris, metallic objects, non-metallic objects, rocks, rain, chemical compounds, aerosols, clouds and even single molecules, just to name a few) in a direction within a range of scanning angles. In some embodiments consistent with the present disclosure, scanner 108 may include, among others, a micromachined mirror assembly having a 2D scanning mirror, such as MEMS mirror 110 that is individually rotatable about a first axis and a second axis. MEMS mirror 110 may be part of a packaged micro-mirror 150.

Packaged micro-mirror 150 may include a micro-mirror array bonded to a package substrate using a first die attach material and a second die attach material. The first die attach material may have a first Young’s modulus, which is lower than the Young’s modulus of the second die attach material. In some embodiments, the first die attach material may be a non-conductive material with a Young’s modulus low enough that can relieve the mechanical stress associated with CTE mismatch, thereby limiting deformation to the micro-mirror die. On the other hand, the second die attach material may be conductive and provide an electrical connection to the micro-mirror die. For example, an external controller (not shown) may be used to apply various voltages to the micro-mirror die during a scanning procedure via the conductive die attach material. Thus, the electrical connection provided by the second die attach material may ground a die substrate of the micro-mirror die or apply a bias voltage to the die substrate of the micro-mirror die.

In some embodiments, at each time point during the scan, scanner 108 may steer light from the light source 106 in a direction within a range of scanning angles by rotating the micromachined mirror assembly concurrently (also referred to herein as “simultaneously”) about the first axis and the second axis. The range of scanning angles can be affected by, among others, the optical divergence of the outgoing laser beam 109. By limiting deformation to the micro-mirror die, the optical divergence of laser beam 109 may be reduced, thereby increasing the range of angles that can be scanned by LiDAR system 100 with a high-degree of precision. The first die attach material and the second die attach material may be arranged in any possible configuration. A few non-limiting examples of such arrangements are depicted in FIGS. 2A, 2B, 2C, 2D, 2E, and 2F.

The micromachined mirror assembly may include various components that enable, among other things, the rotation of the MEMS mirror 110 around different axes. For example, the components, e.g., a 2D scanning mirror (e.g., MEMS mirror 110), a first driver of a first type (e.g., electrostatic) configured to rotate the scanning mirror around a first axis, a second driver of a second type (e.g., piezoelectric) configured to rotate the scanning mirror around a second axis, at least one first torsion spring positioned along the first axis and associated with the first driver, at least one second torsion spring positioned along the second axis and associated with the second driver, a plurality of anchors, a gimbal, and/or one or more silicon beams on which the piezoelectric films of the second driver are formed, just to name a few. In certain aspects, one or more of the components of scanner 108 may be formed on a single crystal silicon. For example, the scanning mirror, the first driver, the second driver, and one or more layers of the micro-mirror die may be formed on a single crystal silicon.

Still referring to FIG. 1, in some embodiments, receiver 104 may be configured to detect a returned laser beam 111 returned from object 112. The returned laser beam 111 may be in a different direction from laser beam 109. Receiver 104 can collect laser beams returned from object 112 and output electrical signals reflecting the intensity of the returned laser beams. Upon contact, laser light can be reflected by object 112 via backscattering, e.g., such as Raman scattering and fluorescence. As illustrated in FIG. 1, receiver 104 may include a lens 114 and a photodetector 120. Lens 114 may be configured to collect light from a respective direction in its FOV and converge the laser beam to focus before it is received on photodetector 120. At each time point during the scan, returned laser beam 111 may be collected by lens 114. Returned laser beam 111 may be returned from object 112 and have the same wavelength as laser beam 109.

Photodetector 120 may be configured to detect returned laser beam 111 returned from object 112. In some embodiments, photodetector 120 may convert the laser light (e.g., returned laser beam 111) collected by lens 114 into an electrical signal 119 (e.g., a current or a voltage signal). Electrical signal 119 may be generated when photons are absorbed in a photodiode included in photodetector 120. In some embodiments of the present disclosure, photodetector 120 may include a PIN detector, a PIN detector array, an avalanche photodiode (APD) detector, a APD detector array, a single photon avalanche diode (SPAD) detector, a SPAD detector array, a silicon photo multiplier (SiPM/MPCC) detector, a SiP/MPCC detector array, or the like.

LiDAR system 100 may also include at least one signal processor 124. Signal processor 124 may receive electrical signal 119 generated by photodetector 120. Signal processor 124 may process electrical signal 119 to determine, for example, distance information carried by electrical signal 119. Signal processor 124 may construct a point cloud based on the processed information. Signal processor 124 may include a microprocessor, a microcontroller, a central processing unit (CPU), a graphical processing unit (GPU), a digital signal processor (DSP), or other suitable data processing devices.

FIG. 2A illustrates a first diagram of an exemplary package substrate assembly 200, according to embodiments of the disclosure. FIG. 2B illustrates a first diagram of an exemplary packaged micro-mirror 210 that includes the package substrate assembly 200 of FIG. 2A, according to embodiments of the disclosure. FIG. 2C illustrates a second diagram of an exemplary package substrate assembly 220, according to embodiments of the disclosure. FIG. 2D illustrates a second diagram of an exemplary packaged micro-mirror 230 that includes the package substrate assembly 220 of FIG. 2C, according to embodiments of the disclosure. FIG. 2E illustrates a third diagram of an exemplary package substrate assembly 240, according to embodiments of the disclosure. FIG. 2F illustrates a third diagram of an exemplary packaged micro-mirror 250 that includes the package substrate assembly 240 of FIG. 2E, according to embodiments of the disclosure. FIGS. 2A-2F will be described together.

Referring to FIGS. 2A, 2C, and 2E, each of the package substrate assemblies 200, 220, and 240 may include a package substrate 202, a first die attach material 204, and a second die attach material 206. As shown in FIGS. 2A, 2C, and 2E, first die attach material 204 and second die attach material 206 may be arranged on package substrate 202 in various configurations. The configurations shown in FIGS. 2A, 2C, and 2E are intended to be illustrative and not limiting. It should be readily understood by one of ordinary skill that first die attach material 204 and second die attach material 206 may be arranged on package substrate 202 in any possible configuration and is not limited to the examples shown in FIGS. 2A, 2C, and 2E.

In some embodiments, package substrate 202 may include a ceramic material, such as aluminum nitride, aluminum oxide, and/or silicon nitride, just to name a few. First die attach material 204 may include a non-conductive material. The non-conductive material may include, e.g., a non-conductive adhesive, a non-conductive epoxy, a non-conductive die attach film, Nitto ELEP Mount™ (EM)-700 die attach film (DAF) (Young’s modulus of 3.7 megapascal (MPa) at 25° C.), Nitto EM-710 DAF (Young’s modulus of 3 MPa at 25° C.), and/or Hitachi Chemical FH-900 (Young’s modulus of 200 MPa at 35° C.), just to name a few. In some embodiments, first die attach material 204 may have a Young’s modulus between, e.g., 1 MPa to 1 gigapascal (GPa). However, in some embodiments, first die attach material 204 may have a Young’s modulus less than 1 MPa. First die attach material 204 may have a Young’s modulus between, e.g., 100 MPa to 1000 MPa, in some embodiments, depending on the temperature.

On the other hand, second die attach material 206 may include a conductive material. The conductive material may include, e.g., a metal, a conductive alloy, a conductive adhesive, a conductive epoxy, a conductive die attach film, EPO-TEK® H20E, LOCTITE® ABLESTIK Ablebond JM7000, LOCTITE® ABLESTIK Ablefilm ECF561E, and/or AI Technology Inc. TC8750, just to name a few. In some embodiments, second die attach material 206 may have a Young’s modulus up to or greater than 2 GPa due to the inclusion of metallic components.

In the example arrangement depicted in FIGS. 2A and 2B, first die attach material 204 is positioned in four places on package substrate 202. As shown in FIG. 2B, micro-mirror die 208 is attached to package substrate 202 via first die attach material 204 near its corners and second die attach material 206 near its center. First die attach material 204 may provide physical connection to stabilize the die attachment between package substrate 202 and micro-mirror die 208. Due to its low Young’s modulus, it also helps relieve, to a certain extent, the mechanical stress caused by the CTE mismatch between package substrate 202 and micro-mirror die 208. On the other hand, second die attachment material 206 may provide electrical connection between package substrate 202 and micro-mirror die 208. By placing it near the center, the deformation effect due to its high Young’s modulus is minimized. In this arrangement, first die attach material 204 is proximate to a peripheral region/corner regions of micro-mirror die 208, and second die attach material 206 is in contact with a central region of micro-mirror die 208.

Still referring to FIGS. 2A and 2B, deformation to micro-mirror die 208 may also be caused by the expansion and/or contraction of second die attach material 206. Thus, by positioning first die attach material 204 symmetrically around second die attach material 206, this mechanical stress may also be relieved, which may further mitigate deformation of micro-mirror die 208. Moreover, by limiting second die attach material 206 to a single area, deformation to micro-mirror die 208 due to expansion and/or contraction of second die attach material 206 may be limited. Also, by placing first die attach material 204 to four regions, the amount of deformation to micro-mirror die 208 caused by expansion and/or contraction of first die attach material 204 may be limited. Still further, because first die attach material 204 is positioned proximate to the corners of micro-mirror die 208, micro-mirror die 208 may be prevented from contacting package substrate 202 and/or becoming unattached in the event of a jarring movement, such as when an autonomous vehicle hits a bump in the road. Thus, the configuration of materials within exemplary packaged micro-mirror 210 of FIG. 2B may achieve an optimized FOV by limiting deformation of micro-mirror die 208, minimizing optical divergence, and preventing damage to micro-mirror die 208.

In the example arrangement depicted in FIGS. 2C and 2D, first die attach material 204 forms a continuous border proximate to a peripheral region of package substrate 202. Furthermore, by positioning first die attach material 204 symmetrically around second die attach material 206, mechanical stress caused by the expansion and/or contraction of second die attach material 206 may be reduced evenly, which may reduce deformation of micro-mirror die 208. Still further, because first die attach material 204 is formed as a continuous border, micro-mirror die 208 may be more robust to sudden movement than the micro-mirror die 208 in the example arrangement depicted in FIGS. 2A and 2B. However, because a larger amount of first die attach material 204 contacts micro-mirror die 208, micro-mirror die 208 may experience a larger amount of deformation caused by expansion and/or contraction of first die attach material 204, as compared with the arrangement depicted in FIG. 2B. Regardless, the configuration of materials within exemplary packaged micro-mirror 230 of FIG. 2D may still achieve a larger FOV, as compared with conventional packaged micro-mirrors.

In the example arrangement shown in FIGS. 2E and 2F, first die attach material 204 is positioned in three locations proximate to a perimeter region of package substrate 202, and second die attach material 206 is positioned in one location proximate to the perimeter region. By limiting die attach material to only four periphery locations, deformation of micro-mirror die 208 by CTE mismatch between first die attach material 204 and second die attach material 206 may be reduced, as compared to those arrangements depicted in FIGS. 2A, 2B, 2C, and 2D. Even though first die attach material 204 is not positioned symmetrically around second die attach material 206, the limited amount of die attach material may reduce the deformation of micro-mirror die 208 so that a desirable FOV may still be achieved.

The above-described arrangements of die attach material are provided by way of example and not limitation. First die attach material 204 and second die attach material 206 may be formed with different shapes, sizes, number of locations, thicknesses, optimized ratios of first die attach material 204/second die attach material 206, and/or amounts, depending on the desired FOV.

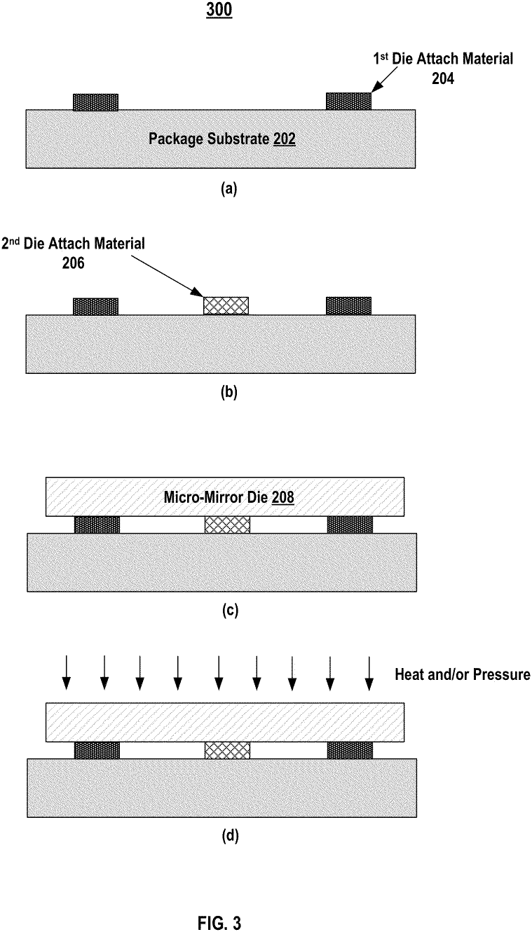

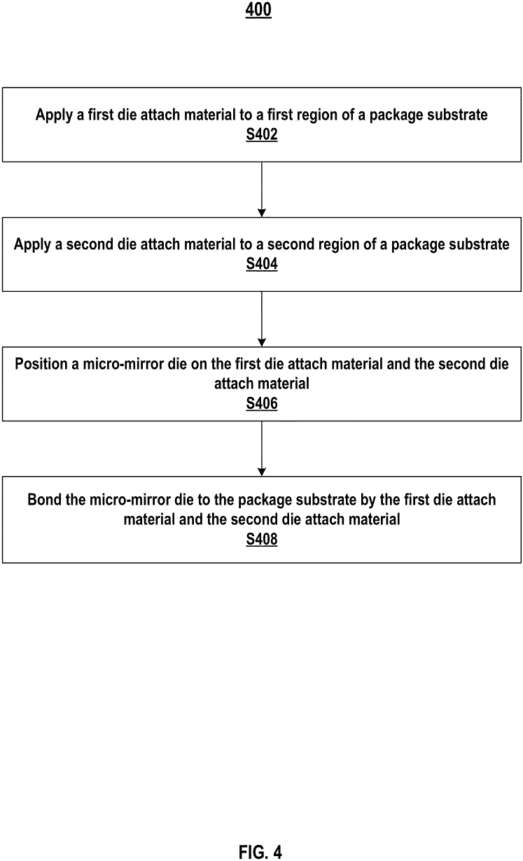

FIG. 3 illustrates an exemplary process flow 300 for assembling packaged micro-mirror 150 depicted in FIGS. 1, 2A, 2B, 2C, 2D, 2E and/or 2F, according to embodiments of the disclosure. FIG. 4 illustrates a flowchart of an exemplary method 400 of assembling packaged micro-mirror 150 depicted in FIGS. 1, 2A, 2B, 2C, 2D, 2E and/or 2F, according to embodiments of the disclosure. Method 400 may include steps S402-S408 as described below. Stages (a)-(d) in FIG. 3 and steps S402-S408 in FIG. 4 may be performed by any type of assembly system and/or device without departing from the scope of the present disclosure. It is to be appreciated that some of the steps may be optional, and some of the steps may be performed simultaneously, or in a different order than shown in FIG. 4. FIGS. 3 and 4 will be described together.

Referring to FIG. 4, the fabrication process may begin at step S402. At S402, first die attach material 204 may be applied to package substrate 202. An example of first die attach material 204 formed on package substrate 202 is illustrated at stage (a) in FIG. 3. First die attach material 204 may be formed on package substrate 202 by, e.g., thin-film deposition, spraying, droplets, placement, application, etc. Package substrate 202 may be formed of a ceramic material, such as aluminum nitride, aluminum oxide, and/or silicon nitride, just to name a few. First die attach material 204 may include a non-conductive material, such as a non-conductive adhesive, a non-conductive epoxy, a non-conductive die attach film, Nitto EM-700 DAF (Young’s modulus of 3.7 MPa at 25° C.), Nitto EM-710 DAF (Young’s modulus of 3 MPa at 25° C.), and/or Hitachi Chemical FH-900 (Young’s modulus of 200 MPa at 35° C.), just to name a few. In some embodiments, first die attach material 204 may have a Young’s modulus between, e.g., 1 MPa to 1 GPa. First die attach material 204 may be applied in any amount, number of locations, shapes, sizes, thicknesses, and/or an optimized ratio of first die attach material 204/second die attach material. Non-limiting example arrangements of first die attach material 204 on package substrate 202 are depicted in FIGS. 2A-2F.

At S404, second die attach material 206 may be applied to package substrate 202. An example of second die attach material 206 formed on package substrate 202 is illustrated at stage (b) in FIG. 3. Second die attach material 206 may be formed on package substrate 202 by, e.g., thin-film deposition, spraying, droplets, placement, application etc. Second die attach material 206 may include a conductive material, such as a metal, a conductive alloy, a conductive adhesive, a conductive epoxy, a conductive die attach film, EPO-TEK® H20E, LOCTITE® ABLESTIK Ablebond JM7000, LOCTITE® ABLESTIK Ablefilm ECF561E, and/or AI Technology Inc. TC8750, just to name a few. In some embodiments, second die attach material 206 may have a Young’s modulus up to or greater than 2 GPa. Non-limiting example arrangements of second die attach material 206 on package substrate 202 are depicted in FIGS. 2A-2F.

At S406, a micro-mirror die 208 may be positioned over first die attach material 204 and second die attach material 206. An example of micro-mirror die 208 positioned on first die attach material 204 and second die attach material 206 is illustrated at stage (c) in FIG. 3. Micro-mirror die 208 may include, among others, a micro-mirror array (e.g., MEMS mirror 110), a micro-mirror substrate (also referred to as a “die substrate”), actuators, springs, electrical connections, etc. Micro-mirror die may include different layers of material, such as silicon, silicon dioxide, silicon nitride, a reflective coating, etc.

At S408, micro-mirror die 208 may be bonded to package substrate 202 by first die attach material 204 and second die attach material 206. An example of micro-mirror die 208 bonded to package substrate 202 by first die attach material 204 and second die attach material 206 is illustrated at stage (d) in FIG. 3. For example, heat and/or pressure may be applied to the packaged micro-mirror so that first die attach material 204 and second die attach material 206 form an adhesive bond so that micro-mirror die 208 is attached to package substrate 202. After the application of heat and/or pressure, packaged micro-mirror 150 may be included in scanner 108.

Thus, by using a non-conductive die attach material (first die attach material 204) with a low Young’s modulus to provide the physical connection, in addition to a conductive die attach material (second die attach material 206) with a higher Young’s modulus to provide the electrical connection, a packaged micro-mirror 150 that achieves an optimized FOV may be provided.

It will be apparent to those skilled in the art that various modifications and variations can be made to the disclosed system and related methods. Other embodiments will be apparent to those skilled in the art from consideration of the specification and practice of the disclosed system and related methods.

It is intended that the specification and examples be considered as exemplary only, with a true scope being indicated by the following claims and their equivalents.

What is claimed is:

1. A packaged micro-mirror for an optical sensing system, comprising:
a package substrate; and
a micro-mirror die attached to the package substrate through a first die attach material and a second die attach material,
wherein the first die attach material has a first Young’s modulus and the second die attach material has a second Young’s modulus higher than the first Young’s modulus, and
wherein at least one of the first die attach material or the second die attach material is a conductive material forming an electrical connection between the micro-mirror die and the package substrate.

2. The packaged micro-mirror of claim 1, wherein:
the first die attach material is a non-conductive epoxy, and
the second die attach material is a conductive epoxy.

3. The packaged micro-mirror of claim 1, wherein the first die attach material is larger in size than the second die attach material.

4. The packaged micro-mirror of claim 1, wherein the first die attach material is attached to a peripheral region of the micro-mirror die.

5. The packaged micro-mirror of claim 1, wherein the second die attach material is attached to a central region of the micro-mirror die.

6. The packaged micro-mirror of claim 1, wherein the first die attach material includes a plurality of epoxy films attached to different regions of the micro-mirror die.

7. The packaged micro-mirror of claim 6, wherein:
the micro-mirror die is in a rectangular shape, and
the first die attach material includes four epoxy films each attached to a different comer region of the micro-mirror die.

8. The packaged micro-mirror of claim 1, wherein the second die attach material includes a single epoxy film attached to the micro-mirror die.

9. The packaged micro-mirror of claim 1, wherein:
the package substrate is formed of a first material and the micro-mirror die is formed of a second material, and
the first material has a first coefficient of thermal expansion (CTE) and the second material has a second CTE smaller than the first CTE.

10. The packaged micro-mirror of claim 1, wherein the electrical connection is configured to ground a die substrate of the micro-mirror die or apply a bias voltage to the die substrate of the micro-mirror die.

11. A scanner for an optical sensing system, comprising:
a packaged micro-mirror comprising:
a package substrate; and
a micro-mirror die attached to the package substrate through a first die attach material and a second die attach material,
wherein the first die attach material has a first Young’s modulus and the second die attach material has a second Young’s modulus higher than the first Young’s modulus,
wherein at least one of the first die attach material or the second die attach material is a conductive material forming an electrical connection between the micro-mirror die and the package substrate.

12. A fabrication method of a packaged micro-mirror, comprising:
applying a first die attach material to a first region of a package substrate;
applying a second die attach material to a second region of the package substrate;
positioning a micro-mirror die in contact with the first die attach material and the second die attach material; and
bonding the micro-mirror die to the package substrate by the first die attach material and the second die attach material,
wherein the first die attach material has a first Young’s modulus and the second die attach material has a second Young’s modulus higher than the first Young’s modulus.

13. The fabrication method of claim 12, wherein:
at least one of the first die attach material or the second die attach material is a conductive epoxy, and
the fabrication method further comprises:
forming an electrical connection between the micro-mirror die and the package substrate.

14. The fabrication method of claim 13, wherein the electrical connection is configured to ground a die substrate of the micro-mirror die or apply a bias voltage to the die substrate of the micro-mirror die.

15. The fabrication method of claim 13, wherein the first die attach material is a non-conductive epoxy, and the second die attach material is a conductive epoxy.

16. The fabrication method of claim 12, wherein the bonding the micro-mirror die to the package substrate by the first die attach material and the second die attach material further comprises attaching the first die attach material to a peripheral region of the micro-mirror die.

17. The fabrication method of claim 12, wherein:
the second die attach material includes a single epoxy film, and
the bonding the micro-mirror die to the package substrate by the first die attach material and the second die attach material further comprises attaching the second die attach material to a central region of the micro-mirror die.

18. The fabrication method of claim 12, wherein:
the first die attach material includes a plurality of epoxy films, and
the bonding the micro-mirror die to the package substrate by the first die attach material and the second die attach material further comprises attaching the plurality of epoxy films to different regions of the micro-mirror die.

19. The fabrication method of claim 18, wherein:
the micro-mirror die is in a rectangular shape,
the first die attach material includes four epoxy films, and
the bonding the micro-mirror die to the package substrate by the first die attach material and the second die attach material further comprises attaching each epoxy film to a corner of the micro-mirror die.

20. The fabrication method of claim 12, further comprising:
forming the package substrate using a first material and forming the micro-mirror die using a second material,
wherein the first material has a first coefficient of thermal expansion (CTE) and the second material has a second CTE smaller than the first CTE.
